(19) United States
(12) Patent Application Publication
(10) Pub. No.: US 2026/0057123 A1
(43) Pub. Date: Feb. 26, 2026

(54) SENSOR-BASED DIGITAL TWIN SYSTEM FOR BRIDGE ANALYSIS

(71) Applicant: University of South Carolina, Columbia, SC (US)

(72) Inventors: Li Ai, Knoxville, TN (US); Paul Ziehl, Irmo, SC (US)

(21) Appl. No.: 19/250,977

(22) Filed: Jun. 26, 2025

Related U.S. Application Data
(60) Provisional application No. 63/686,916, filed on Aug. 26, 2024.

(51) Int. Cl. G06F 30/13

(52) U.S. Cl. CPC G06F 30/13

(57) ABSTRACT

A sensor-based digital twin system operable to determine bridge load rating, enhance bridge safety, extend infrastructure lifespan, and reduce maintenance costs of a bridge. The sensor-based digital twin system uses real-time data to update virtual models of physical assets that enables a more dynamic and precise understanding of bridge conditions, which allows for real-time monitoring of a load assessment of a bridge and can identify the need for bridge maintenance.

### CROSS-REFERENCE TO RELATED APPLICATIONS

This application claims the benefit of U.S. Provisional Patent Application No. 63/686,916, filed on August, 26, 2024.

### INCORPORATION BY REFERENCE

The disclosure of U.S. Provisional Ser. No. 63/686,916 , filed on Aug. 26, 2024 are hereby incorporated by reference for all purposes as if presented herein in their entirety.

### FIELD OF THE INVENTION

The present invention relates generally a sensor-based digital twin system for bridge analysis. In some embodiments, the specification relates to a sensor-based digital twin system operable to determine bridge load rating, enhance bridge safety, extend infrastructure lifespan, and reduce maintenance costs of a bridge.

### DESCRIPTION OF RELATED ART

Conventional infrastructure maintenance heavily relies on manual inspections and static models, which are inadequate to meet the demands of aging infrastructure and increasing traffic loads. Digital twins utilize real-time data from advanced sensors and monitoring systems to update virtual models of physical assets, enabling a more dynamic and precise understanding of bridge conditions. The methods and systems described herein allows for real-time monitoring and can identify the need for proactive maintenance, significantly improving load assessment and extending the lifespan of bridge components.

Civil infrastructure, particularly bridges, plays a crucial role in the transportation network, underpinning economic activity and public safety. Maintaining these structures is a significant challenge due to aging infrastructure, increased traffic loads, and environmental factors that accelerate wear and tear. A substantial portion of the bridges in the United States are classified as structurally deficient or functionally obsolete, which necessitates frequent inspections and maintenance. Conventional methods of load rating and inspection, while effective to a certain extent, are often labor-intensive, costly, and are less reliable due to their dependence on manual processes and static models. To address these challenges, it is desirable to leverage digital twin technology, which generates a virtual representation of a physical asset that updates in real-time based on data collected from the asset itself. By integrating digital twins with advanced field monitoring data, as presented herein, users can achieve a more accurate and dynamic understanding of the condition of a bridge structure, leading to better maintenance decisions and enhanced safety.

### SUMMARY

Described herein are embodiments of a digital twin system. In some embodiments, the digital twin system beneficially provides end users with accurate and meaningful information that they can use when determining the current bridge load rating and maintenance status of a bridge.

In some embodiments, the digital twin system knows the state of respective bridges when they are new (i.e., their “new state”) based on the bridge models for each real-world bridge assembly. For example, the digital twin system can have access to the bridge models for some or all of the bridges installed in a county, state or country.

As described herein, digital twin systems and methods constructs digital replicas of a bridge's physical assets and continuously updates them with real-time data collected by various sensors and monitoring systems. This derived digital twin model reflects the behavior and condition of the bridge, allowing for real-time analysis and prediction of the behavior of the bridge, which allows for early detection of potential problems and timely intervention, thereby reducing the risk of structural failure and extending the service life of the bridge. Additionally, such a derived digital twin model can provide more accurate bridge load ratings than traditional methods that typically rely on static models and periodic inspections.

Digital twin systems and methods further allows for significant cost savings as a result of the reduced need for labor-intensive manual inspections and their associated cost due to automation and as a result of the production of optimized maintenance schedules and interventions based on real-time data, which prevents unnecessary conditions to the bridge and can extend the life of bridge components. Digital twins also improve the overall safety and reliability of bridge infrastructure. By providing comprehensive, up-to-date information about the condition of the bridge, such a digital twin model an allow an end operator to make more proactive informed decisions the mechanical status and reliability of the bridge and about the need for maintenance and conditions, which can help reduce risk and ensure the safety of traveling across bridges.

In some embodiments, the digital twin system monitors the mechanical status and reliability of the bridge based on one or more of the following: (1) vehicle load data, which is derived from data obtained from at least one acoustic emission sensor disposed thereon the bridge; (2) bridge strain data which is collected from at least one strain sensor disposed thereon the bridge; and (3) bridge data and/or condition data, which is collected from sources that observe the condition of the bridge, such as inspectors, drone inspections, and the like.

In some embodiments, new instances of the acoustic emission (AE) data (and the derived vehicle load data), bridge data, bridge strain data, and condition data can be repeatedly received by the digital twin system for a respective bridge over a period of time. The state or model of the digital twin bridge is updated by the digital twin system based on instances of the derived vehicle load data, the bridge strain data, bridge data, and the condition data that are received over the period of time, thereby enabling the digital twin system to track the mechanical condition of the bridge via the updated model of the digital twin bridge and to allow for the determination of a bridge rating factor based on the updated digital twin bridge model.

In aspects, the updated digital twin bridge model is a digitized version of the real-world bridge which replicates the condition of: (1) the bridge as a whole as indicated by the derived vehicle load data, the bridge strain data, the bridge data, and the condition data; and (2) individual components of the bridge as indicated by the derived vehicle load data, the bridge strain data, and the condition data. The digital twin system models how the real-world bridge will perform in the future based on the current state of the bridge as indicated by the updated digital twin bridge model for that bridge.

In some embodiments, the digital twin system is operable to generate a report for each bridge it tracks. The report describes, for example, one or more of the following: a bridge loading factor for the bridge based on the updated digital twin bridge model; the a mechanical condition of the bridge based on updated digital twin bridge model; whether the bridge should receive maintenance based on updated digital twin bridge model; and an estimate of how the bridge will perform under vehicular loads based on updated digital twin bridge model.

In some embodiments, a Web Application Programming Interface (WebAPI) and/or Graphical User Interface (GUI) can be used to enable end operators to access the digital twin system and generate the report. In some embodiments, the report includes accurate and meaningful information to assist them in estimating bridge load ratings for the bridge. In some embodiments, the report and the estimated bridge load rating is accurate and meaningful because it is based on the actual sensor measurements recorded by the AE sensors and the strain sensors thereon the bridge whose condition can described by the report, as well how the bridge is estimated to perform under vehicular loads in the future.

A system of one or more computers can be configured to perform particular operations or actions by virtue of having software, firmware, hardware, or a combination of them installed on the system that in operation causes the system to perform the actions. One or more computer programs can be configured to perform particular operations or actions by virtue of including instructions that, when executed by data processing apparatus, cause the apparatus to perform the actions.

One general aspect includes a method including: generating a digital twin of a bridge, receiving digital data recorded by a sensor and describing the bridge as it exists in a real-world, and updating the digital twin of the bridge based on the digital data describing the bridge so that the digital twin is consistent with a condition of the bridge as it exists in the real-world. Other embodiments of this aspect include corresponding computer systems, apparatus, and computer programs recorded on one or more computer storage devices, each configured to perform the actions of the methods.

In embodiments, the exemplary method of developing and utilizing digital twins for bridge load rating can include several steps. First, vehicle loads can be derived using acoustic emission (AE) data captured by AE sensors installed on the bridge. The derived vehicle load data can then be applied to a high-fidelity finite element model (the digital twin bridge model) of the bridge to simulate its structural response. In operation, it is contemplated that the high-fidelity finite element model of the digital twin bridge model of the bridge can be continuously updated and validated with actual derived vehicular load data and actual strain measurement data captured by stain sensors installed on the bridge to ensure accuracy and to update the digital twin bridge model of the bridge. Additionally, visual and/or inspections can be used to detect surface cracks and other defects, which can then be used to further update the condition data that can be used in the updated digital twin bridge model of the bridge and in a determination of a bridge's load rating factor.

Implementations can include one or more of the following features. The method where the digital data describes a state of the bridge. The method where multiple instances of the digital data are received over time as part of a feedback loop and the digital twin is recursively updated based on the digital data received in the feedback loop. The method further including generating an electronic report describing the bridge based on the updated digital twin and providing the electronic report to an electronic device. Implementations of the described techniques can include hardware, a method or process, or computer software on a computer-accessible medium.

One general aspect includes a system including: a non-transitory memory storing digital data recorded by a sensor and describing a bridge as it exists in a real-world; and a processor that is communicatively coupled to the non-transitory memory, where the non-transitory memory stores computer code which, when executed by the processor, causes the processor to: generate a digital twin of the bridge; and update the digital twin of the bridge based on the digital data describing the bridge so that the digital twin is consistent with a condition of the bridge as it exists in the real-world. Other embodiments of this aspect include corresponding computer systems, apparatus, and computer programs recorded on one or more computer storage devices, each configured to perform the actions of the methods.

Implementations can include one or more of the following features. The computer program product where the digital data describes a load state of one or more bridge components of the bridge. The computer program product where AE sensors and strain sensors are elements of the bridge. Implementations of the described techniques can include hardware, a method or process, or computer software on a computer-accessible medium.

Various implementations described in the present disclosure can include additional systems, methods, features, and advantages, which can not necessarily be expressly disclosed herein but will be apparent to one of ordinary skill in the art upon examination of the following detailed description and accompanying drawings. It is intended that all such systems, methods, features, and advantages be included within the present disclosure and protected by the accompanying claims.

### DESCRIPTION OF THE FIGURES

The features and components of the following figures are illustrated to emphasize the general principles of the present disclosure. Corresponding features and components throughout the figures can be designated by matching reference characters for the sake of consistency and clarity.

FIG. 1 is a schematic diagram illustrating an exemplary computer system for a digital twin system according to some embodiments.

FIG. 2 is a schematic block diagram illustrating an exemplary computer process flow for deriving vehicular load data from sensed acoustic emission data in a processor programmed to execute probabilistic machine learning programming and for communicating strain sensor data streams, vehicular load data streams, and acoustic emission data streams to a digital twin system according to some embodiments.

FIG. 3 includes a flowchart of an example method for providing a digital twin service for a real-world bridge according to some embodiments.

FIG. 4 includes a flowchart of an example method for providing a digital twin service for a real-world bridge according to some embodiments.

FIG. 5 is a schematic block diagram illustrating a process flow for a digital twin system to provide report data according to some embodiments.

FIG. 6 is a block diagram illustrating an overview of an operating environment for the digital twin system for determining a bridge load rating and how the digital twin system fits into the bridge analysis methodology according to some embodiments.

FIG. 7 is an exemplary GUI report page used by the operator for initiating the determination of a bridge load rating for a particular bridge using the digital twin system methodology according to some embodiments.

FIGS. 8A and 8B are charts illustrating the laboratory results demonstrating the efficacy using a machine learning model to determine vehicular loads on a bridge based on sensed acoustic emissions (AE). FIG. 8A shows sensed AE signals after a load step is applied to an experimental bridge span, where each dot represents a sensed AE signal. FIG. 8B shows the experimental results, for example, for load step L2 (the left most column), 112 AE signals indicated a vehicle load level of L2, 48 AE signals indicated an impact force of L3, 21 AE signals leaned towards an impact force of L4, and 19 AE signals inferred an impact force of L5. Considering all these factors, the majority of decisions supported a load level of L2 and the machine learning model concluded that the applied load level was L2, which corresponded with the actual condition. For load steps with load levels L3, L4, and L5, the results were similar to those of load step L2 and the machine learning model accurately determined the applied load level that corresponded with the actual load condition.

FIG. 9 A-C schematically the step of applying the determined vehicle load, to a high-fidelity digital twin version of the bridge. As show, the exemplary model shown in FIG. 9B shows the high-fidelity digital twin version of a span of the bridge that is pictured in FIG. 9A. In operation, the AE-predicted vehicular load is applied to the high-fidelity digital twin version of the bridge to obtain estimated mechanical responses of the bridge, such as displacement and strain. FIG. 9C displays the results of the high-fidelity digital twin version of a span of the bridge when subjected to the vehicle load.

FIG. 10 illustrates an exemplary bridge condition rating mechanism, which specifically focuses on the spacing between surface cracks in concrete bridges as this spacing is a crucial indicator of potential structural damage. In operation, the rating system is divided into three conditions: Condition 1 (Good), Condition 2 (Fair), and Condition 3 (Poor). Condition 1 (Good) indicates crack spacing greater than 3.0 feet, suggesting minimal structural issues. Conversely, Condition 3 (Poor) indicates crack spacing less than 1 foot, suggesting significant structural problems.

FIG. 11 is a table that matches a condition factor for the bridge based on the Specifications for the National Bridge Inventory. Under this system, the condition factor assigns values to the condition states: Good, Fair, and Poor, which were determined via the exemplary bridge condition rating mechanism shown in FIG. 10. Condition 1 (Good) corresponds to a condition factor of 1.00, indicating the structure is in optimal condition with negligible defects. Condition 2 (Fair) has a condition factor of 0.95, indicating the structural condition is generally acceptable with minor defects. Condition 3 (Poor) has a condition factor of 0.85, indicating significant defects or aging that may threaten the overall integrity of the structure.

### DETAILED DESCRIPTION

The present invention can be understood more readily by reference to the following detailed description, examples, drawings, and claims, and their previous and following description. However, before the present devices, systems, and/or methods are disclosed and described, it is to be understood that this invention is not limited to the specific devices, systems, and/or methods disclosed unless otherwise specified, and, as such, can, of course, vary. It is also to be understood that the terminology used herein is for the purpose of describing particular aspects only and is not intended to be limiting.

The following description of the invention is provided as an enabling teaching of the invention in its best, currently known embodiment. To this end, those skilled in the relevant art will recognize and appreciate that many changes can be made to the various aspects of the invention described herein, while still obtaining the beneficial results of the present invention. It will also be apparent that some of the desired benefits of the present invention can be obtained by selecting some of the features of the present invention without utilizing other features. Accordingly, those who work in the art will recognize that many modifications and adaptations to the present invention are possible and can even be desirable in certain circumstances and are a part of the present invention. Thus, the following description is provided as illustrative of the principles of the present invention and not in limitation thereof.

As used throughout, the singular forms “a,” “an” and “the” include plural referents unless the context clearly dictates otherwise. Thus, for example, reference to “a sensor” can include two or more such sensors unless the context indicates otherwise.

Ranges can be expressed herein as from “about” one particular value, and/or to “about” another particular value. When such a range is expressed, another aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

As used herein, the terms “optional” or “optionally” mean that the subsequently described event or circumstance can or cannot occur, and that the description includes instances where said event or circumstance occurs and instances where it does not.

The word “or” as used herein means any one member of a particular list and also includes any combination of members of that list. Further, one should note that conditional language, such as, among others, “can,” “could,” “might,” or “can,” unless specifically stated otherwise, or otherwise understood within the context as used, is generally intended to convey that certain.

Disclosed are components that can be used to perform the disclosed methods and systems. These and other components are disclosed herein, and it is understood that when combinations, subsets, interactions, groups, etc. of these components are disclosed that while specific reference to each various individual and collective combinations and permutation of these cannot be explicitly disclosed, each is specifically contemplated and described herein, for all methods and systems. This applies to all aspects of this application including, but not limited to, steps in disclosed methods. Thus, if there are a variety of additional steps that can be performed it is understood that each of these additional steps can be performed with any specific embodiment or combination of embodiments of the disclosed methods.

The present methods and systems can be understood more readily by reference to the following detailed description of preferred embodiments and the examples included therein and to the Figures and their previous and following description.

Described herein are embodiments of a digital twin system. In some embodiments, the digital twin system beneficially provides users with accurate and meaningful information that they can use when simulating loads acting on a simulated bridge, determining the vehicle load limit of a bridge, and/or whether maintenance is required to maintain the load capability of a bridge.

In some embodiments, the digital twin system described herein overcomes the deficiencies of the existing solutions by causing a processor to execute one or more of the following steps when executed by the processor: generating a simulated version of the a bridge in its “new state” based on bridge model for that bridge; aggregating vehicle load data, bridge strain data, and condition data that describe changes in the state of the bridge; updating the bridge model of the bridge, i.e., the “digital twin,” based on the vehicle load data, bridge strain data, and the condition data; modeling a future performance of the bridge on a periodic or continual basis, generating a report describing one or more of the load rating of the bridge, whether maintenance on the bridge is required or how the bridge will perform under load, and providing the report to an end user (e.g., using a WebAPI and/or GUI).

In some embodiments, the vehicle load data, bridge strain data, and condition data can be received on a periodic or continual basis. In additional aspects, it is contemplated that the vehicle load data, bridge strain data, and condition data can generally describe degradation in the state of the bridge, but in practice the state can periodically increase, e.g., if a new bridge component is installed or when bridge maintenance is performed.

In optional aspects, it is contemplated that the bridge model can be updated on a periodic or continual basis responsive to the receipt of instances of vehicle load data, bridge strain data, and/or condition data over time.

It is contemplated that the digital twin system has access to bridge design data. The bridge design data is digital data that describes the bridge models, Computer-aided Design (CAD) data, simulation/test results for each bridge. Based on the design data, the digital twin system knows the state of bridges when they are new (i.e., their “new state”). The new state of the bridge is represented in a simulation as a digital twin of the bridge which exists in the real-word. As one will appreciate, the “new” state can reflect the current state of the bridge when initially rendered in the digital twin system. For example, a bridge built 20 years ago can be described as “new” when the present condition of the bridge is initially entered into the system.

In some embodiments, a bridge includes systems and sensors that monitor the condition of the bridge and its components. In some embodiments, a communication unit of the bridge receives acoustic emission (AE) data, bridge strain data, via an in-bridge network which communicatively couples the communication unit to the systems and the sensors of the bridge. The AE data, bridge strain data, is digital data that includes: (1) the AE sensor data that describes the measurements recorded by the bridge's AE sensors, which are indicative of vehicle load data, and (2) the stain sensor data describes the bridge dynamics information measured by the bridge's strain sensors.

In some embodiments, the bridge can include a processor that includes software instructions to communicate with the communication unit of the bridge to aggregate and timestamp the AE data and bridge strain data and to subsequently transmit the AE data and bridge strain data back to the digital twin system which is stored on and executed by a server that is communicatively coupled to a wireless network. For example, the bridge processor can be programmed to communicate aggregated and timestamped sets of the AE data and bridge strain data back to the digital twin system (which operates on a cloud server) at regular intervals via Wi-Fi™, 3G, 4G, Long-term Evolution (LTE), 5G, Direct Short Range Communication (DSRC) or some other form of wireless communication. In another embodiment, the AE data and bridge strain data can be reported back reported back to the digital twin system on a periodic basis, a continual basis, and/or when requested by an operator. Accordingly, the AE data and the bridge strain data function as a first source of digital data for the digital twin system that describes the appreciation and degradation of the of the bridge.

In some respects, an optional feature according to some embodiments is the ability to capture maintenance events that update the operational state of the bridge via reports that are sent are sent by a report system that is operatively connected to the digital twin system. Such communication can be conducted via the cloud server. In operation, the report system can be configured to report the condition data back to the digital twin system so that the condition data can be included in the analysis and functionality provided by the digital twin system. Accordingly, the condition data is a second source of digital data for the digital twin system that describes the appreciation and degradation of the bridge, where the AE data and the bridge strain data, is the first source of such digital data.

In some embodiments, the digital twin system includes software stored on a non-transitory memory. The non-transitory memory is an element of a processor-based computing device such as a server or cloud server. The digital twin system includes code and routines that are operable, when executed by a processor of the computing device, to cause the processor to receive digital data that describes degradation and appreciation events for a bridge that includes bridge sensors and to generate a simulated version of the bridge it monitors. The simulation version of the bridge is referred to herein as a “digital twin.”

In some embodiments, the digital twin system includes a simulation engine for generating the simulated version of the bridge. For example, the digital twin system uses the bridge model for a particular bridge (based on the bridge's particular design and construction) to generate a simulated version of the particular bridge.

In some embodiments, the digital twin system maintains a unique instance of a digital model for each particular bridge it monitors. This unique instance is described as a “bridge model” since it is a version of the digital model that is used to generate a simulation of a particular bridge. In some embodiments, the digital twin system includes a simulation data set that includes the bridge models for each of the bridges monitored by the digital twin system.

The bridge model includes any digital data and information that is necessary for the simulation engine to generate a digital twin of a real-world bridge. In some embodiments, the bridge model is based on design data for the real-world bridge whose digital twin is created using the bridge model. In some embodiments, the digital twin system includes a modeling application that is operable to generate the bridge model for a particular bridge based in part on the design data and, optionally, any AE data (and vehicle load data derived therefrom), bridge strain data, and bridge data that are received for a bridge that is being monitored by the digital twin system.

Additionally, It is contemplated that visual and/or drone inspections can be used to detect surface cracks and other defects in the bridge, which can then be used to further update the bridge model and can also be used in determining bridge condition factors for a calculation of a bridge's load rating factor.

Initially, the bridge model is referred to as a “bridge model” since it represents the version of the bridge as it was constructed, i.e., without any degradation in the state of the bridge, or as currently in existence at the time of the original construction of the digital twin of the bridge, i.e., with degradation of an older bridge being built into the digital twin “new” bridge). As one will appreciate, over the life of a particular bridge, the digital twin system receives reports of vehicle load data (derived from the AE data), bridge strain data, bridge data, and condition data for the particular bridge. The digital twin system modifies particular parameters of the bridge model for this particular bridge based on the degradation/appreciation information included in the vehicle load data, bridge strain data, bridge data, condition data (which can include determined condition factors derived from visual and/or drone inspections be used to detect surface cracks and other defects in the bridge).

A bridge model which reflects the degradation and appreciation for a bridge that occurs over time is referred to as the “modified bridge model.” No other known bridge model uses derived vehicle load data, bridge strain data, bridge data, and condition data to generate a digital twin of a real-world bridge that accurately reflects the current mechanical condition of a bridge and whether maintenance events of the bridge will need to be conducted in the future.

The simulation engine can be any other simulation engine operable, when executed by a processor, to generate a digital simulation (herein “simulation”) for testing and monitoring the operation of a virtual bridge that represents a bridge that exists in the real-world. In operation, the modeling application includes code and routines that are operable, when executed by a processor, to generate bridge model data that describes a bridge model of a bridge. The bridge model data includes data necessary to cause the simulation engine to generate a virtualized version of the real-world bridge.

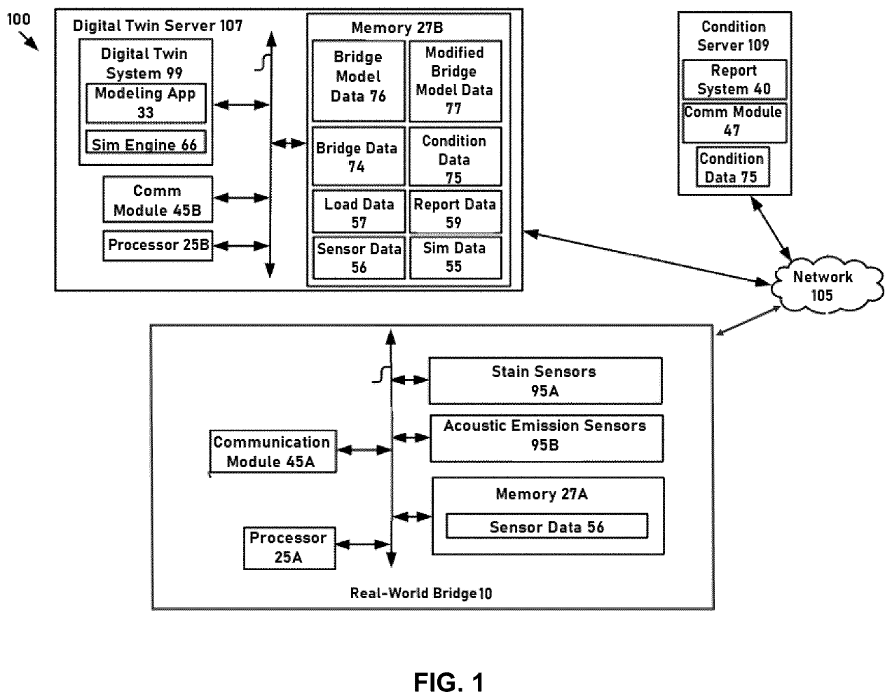

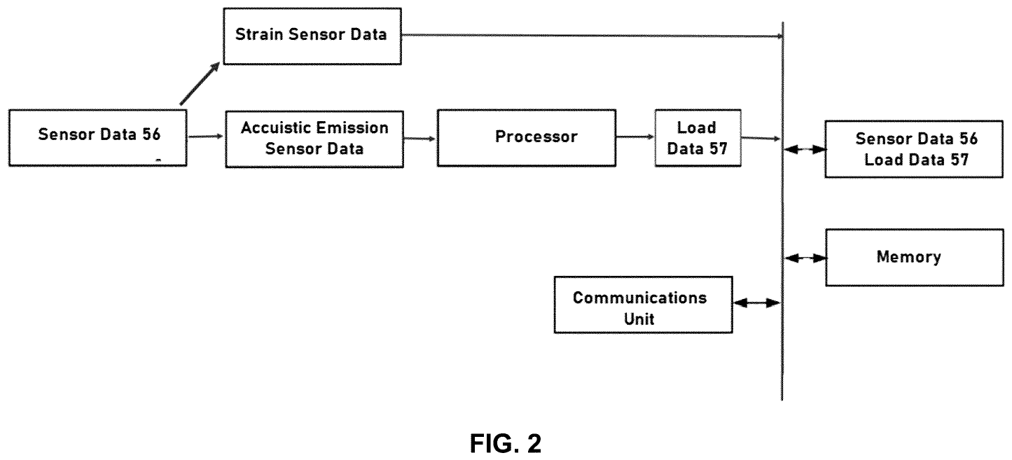

In some embodiments and referring to FIG. 1 and FIG. 2, the bridge model is described by digital data referred to as the “bridge model data” and the modified bridge model is described by digital data described as the “modified bridge model data.” The bridge model and the modified bridge model can be referred to herein collectively or individually as the “bridge model.”In embodiments, the digital twin system includes code and routines that are operable to receive the modified bridge model data as an input and then to perform multiple simulations that can estimate one or more of the following: whether the real-world version of the bridge will need to be conditioned in the near future; and/or how the real-world version of the bridge will perform under vehicular loads. Simulation data is digital data that describes an estimate of maintenance required to be performed on the real-world version of the bridge in the near future and/or how the real-world version of the bridge will perform under various vehicular loads (and what is the estimated bridge load limit ratting of the real-world version of the bridge).

In embodiments, the digital twin system can provide a GUI interface for end operators that can be configured to allow end users the ability to request reports from the digital twin system. The report data can be digital data that describes at least one of: the mechanical condition (or state) of the bridge, whether the bridge will require maintenance in the near future, the bridge load rating of the bridge; and/or how the bridge will perform under vehicular loading. The digital twin system can generate the report data based on the modified bridge model and the simulation data for a particular real-world bridge. In some embodiments, it is contemplated that the digital twin system only generates the simulation data and the report data if the server that operates the digital twin system receives a request for a report for a particular real-world bridge.

In embodiments and referring to FIG. 1, an operating environment 100 for a digital twin system 99 is schematically illustrated. In aspects, the operating environment can include a real-world bridge 10, a digital twin server 107, and a bridge condition server 109. These elements can be communicatively coupled to one another via a network 105. Although one bridge 10, one digital twin server 107, one bridge condition server 109, and one network 105 are depicted, in practice it is contemplated the operating environment 100 can include one or more bridges 10, one or more digital twin servers 107, one or more bridge condition servers 109, or one or more networks 105.

In embodiments, the network 105 can be a conventional type, wired or wireless, and can have numerous different configurations including a star configuration, token ring configuration, or other configurations. Furthermore, in optional aspects, it is contemplated that the network 105 can include a local area network (LAN), a wide area network (WAN) (e.g., the Internet), or other interconnected data paths across which multiple devices and/or entities can communicate. In some optional embodiments, the network 105 can include a peer-to-peer network. In further optional aspects, the network 105 can also be coupled to or can include portions of a telecommunications network for sending data in a variety of different communication protocols.

In some exemplary embodiments, and without limitation, the network 105 can include Bluetooth® communication networks or a cellular communications network for sending and receiving data including via short messaging service (SMS), multimedia messaging service (MMS), hypertext transfer protocol (HTTP), direct data connection, wireless application protocol (WAP), e-mail, DSRC, full-duplex wireless communication, etc. In further exemplary embodiments, and without limitation, the network 105 can also include a mobile data network that can include 3G, 4G, LTE, LTE-V2X, VoLTE or any other mobile data network or combination of mobile data networks.

The network 105 can include one or more communication channels shared among the bridge 10 and the digital twin server 107. Exemplary communication channels can include, without limitation, DSRC, LTE-V2X, full-duplex wireless communication or any other like wireless communication protocol. For example, the network 105 can be used to transmit a DSRC message, a DSRC probe, a Basic Safety Message (BSM) or a full-duplex message including any of the data described herein.

As contemplated, the bridge 10 can be any type of conventional bridge having design and construction data associated therewith. In some embodiments, the bridge 10 can includes one or more of the following elements: a processor 25A; a memory 27A; a communication unit 45A; strain measurement sensors 95A, and acoustic emission sensors 95B. These elements of the real-world bridge 10 can be communicatively coupled to one another via a bus. Although only one of each of these elements are depicted in FIG. 1, in operation the bridge 10 can include one or more processors 25A, one or more memories 27A, one or more communication units 45A, and one or more strain measurement sensors 95A, and one or more and acoustic emission sensors 95B.

The digital twin server 107 is a processor-based computing device. For example, and without limitation, the digital twin server 107 can include one or more of the following types of processor-based computing devices: a personal computer; a laptop; a mainframe; or any other processor-based computing device that is operable to function as a server. The digital twin server 107 can include a hardware server.

In some embodiments, and referring to FIG. 2, the digital twin server 107 can include one or more of the following elements: a processor having a memory; a communication unit suitable for communicating with the digital twin system 99. These elements of the digital twin server 107 can be configured to be communicatively coupled to one another via a bus. The processor of the bridge 10 and the processor 25B of the digital twin server 107 can be referred to herein collectively or individually as the “processor 25” since, for example, the processor 25A of the bridge 10 provides similar functionality to the components of the bridge 10 as does the processor 25B of the digital twin server 107.

Optionally, the processor 25B of the digital twin server 107 can be the overall processor 25 for the system and methods described herein. For similar reasons, the description provided herein uses the following terms when referring to elements that are common to the bridge 10 and the digital twin server 107: the “memory 27” when referring to the memory 27A and the memory 27B, collectively or individually; and the “communication unit 45” when referring to the communication unit 45A, the communication unit 45B, collectively or individually.

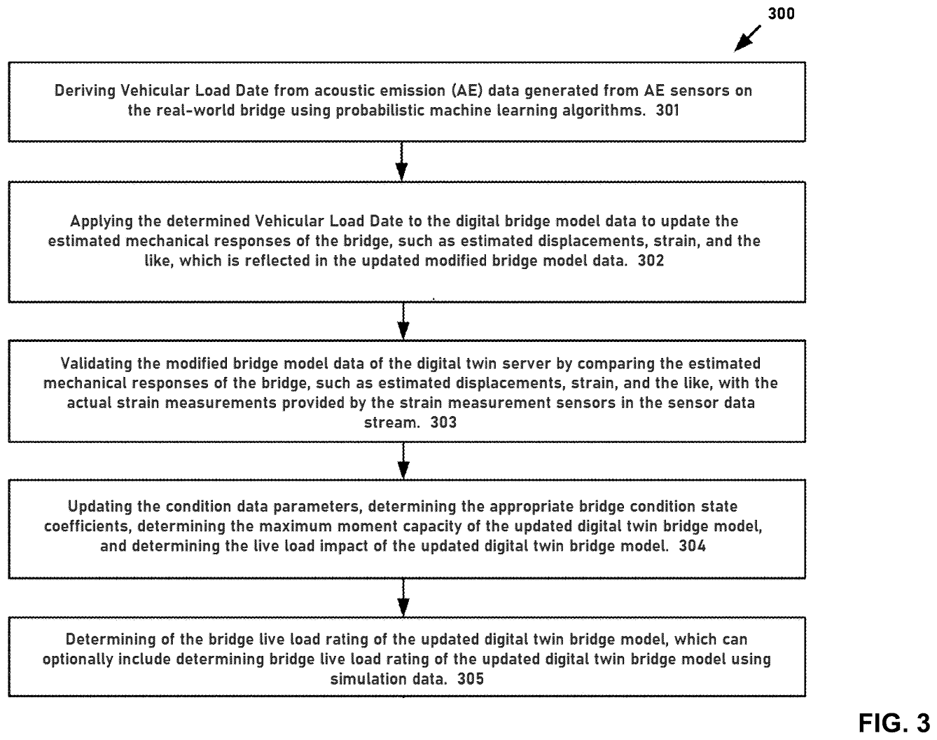

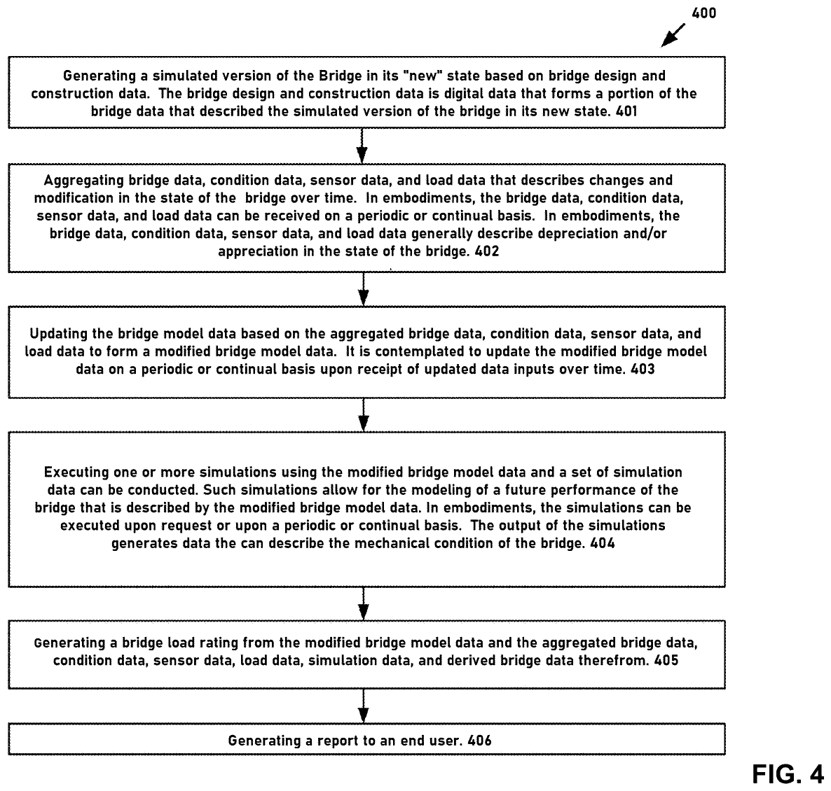

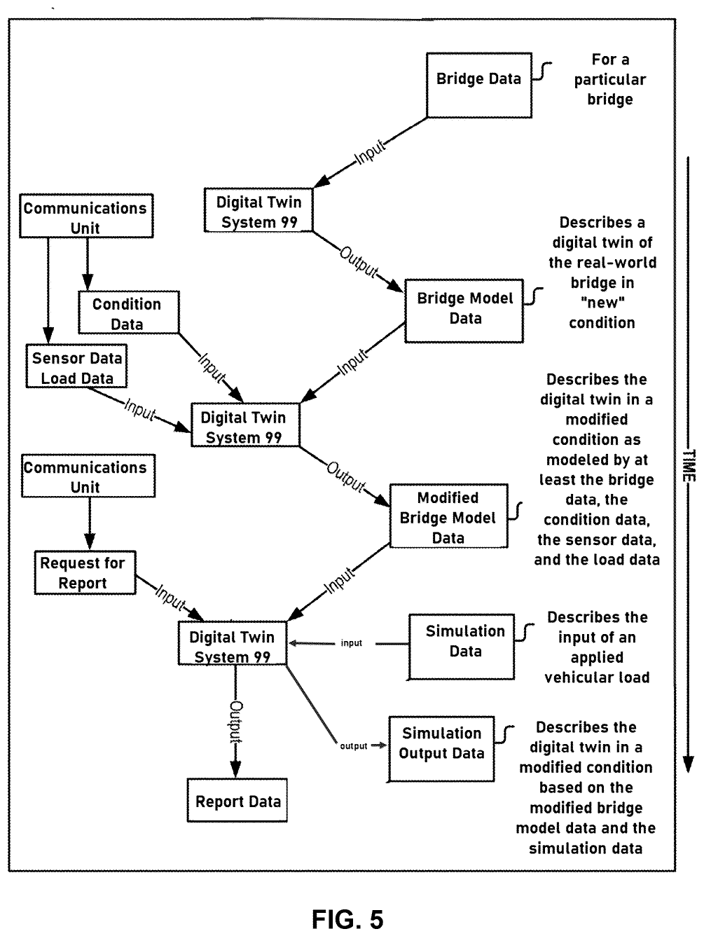

In some embodiments, the processor 125 and the memory 127 can be elements of a bridge computer system that can be operable to cause or control the operation of one or more of the following elements: one or more strain sensors 95A, one or more AE sensors 95B, the communication unit 45; the processor 25; and the memory 27. The bridge computer system can be operable to access and execute the data stored on the memory 27 to provide the functionality described herein. In aspects, the bridge computer system can be configured to be operable to execute one or more of the steps of the method 300 described below with reference to FIGS. 3 and 4. The strain measurement sensors 95A and the acoustic emission sensors 95B of the bridge 10 aid in monitoring the roadway environment and loading of the bridge 10.

Referring to FIG. 3, in exemplary aspects, in a first Step 301, the processor 25 of the bridge 10 or the digital twin server 107 is programmed to derive vehicular load data from acoustic emission data received from the AE sensors. In this step, it is contemplated that the processor 25 can be programmed with probabilistic machine learning algorithms that can be applied to the acoustic emission data to determine the vehicle load data, which data is indicative of applied vehicular loads being applied to at least a portion of the bridge or to the bridge.

In a second Step 302, the processor 25 of the digital twin server can be programed with instructions that when executed applies the determined vehicular load data to the bridge model data to determine the estimated mechanical responses of the bridge, such as estimated displacements, strain, and the like, which is reflected in the creation of an updated modified bridge model data.

In a third Step 303, the processor 25 of the digital twin server can be programed with instructions that when executed validates the modified model data of the digital twin server 107 by comparing the estimated mechanical responses of the bridge with the actual stain measurements provided by the strain measurement sensors 95A and transmitted in the sensor data 56 stream that is stored in memory 27. This step can further include updating the modified bridge digital data to insure that the updated digital twin model accurately reflects the real-world feedback, which can occur in a feedback loop.

In a fourth Step 304, the processor 25 of the digital twin server can be programed with instructions that when executed updates the condition parameters of a bridge load rating equation by determining the appropriate bridge condition state coefficients to apply. Further in Sep 304 it is contemplated that the processor 25 can be programed with instructions that when executed determines the maximum moment capacity of the updated digital twin bridge model and determines the live load impact of the updated digital twin bridge model.

Subsequently, in a fifth Step 305, the processor 25 of the digital twin server can be programed with instructions that when executed allow for the determination of the load rating factors of the digital twin bridge model as modified/updated. The fifth step can be an operator instituted step which can further include selecting the bridge and deck, setting the vehicle type, and providing and integrating all the data required into the bridge load rating equation.

In the first Step 301, it is contemplated that processor 25 of the digital twin server can be programed with instructions that when executed allow for the determination of the vehicle load based on the AE sensor data captured by the AE sensors deployed on-site at the bridge as vehicles pass over the real-world bridge. In exemplary aspects, it is contemplated that the processor 25 can be programed to apply a probabilistic machine learning algorithm for this determination of the vehicle load based on the AE sensor data. Exemplarily, it is contemplated the programed probabilistic machine learning algorithm can receive the AE sensor data stream, which contains a plurality of real-time AE data signals generated by the respective AE sensors as a passing vehicle travels over the real-world bridge. In operation, the programed probabilistic machine learning algorithm can process the real-time AE data signals and provide a result indicative of the probability that the passing vehicle belongs to different vehicle load levels. The processor 25 of the digital twin server can be programed with instructions that when executed allows for the selection of the vehicle load level with the highest probability as the vehicle load of the passing vehicle.

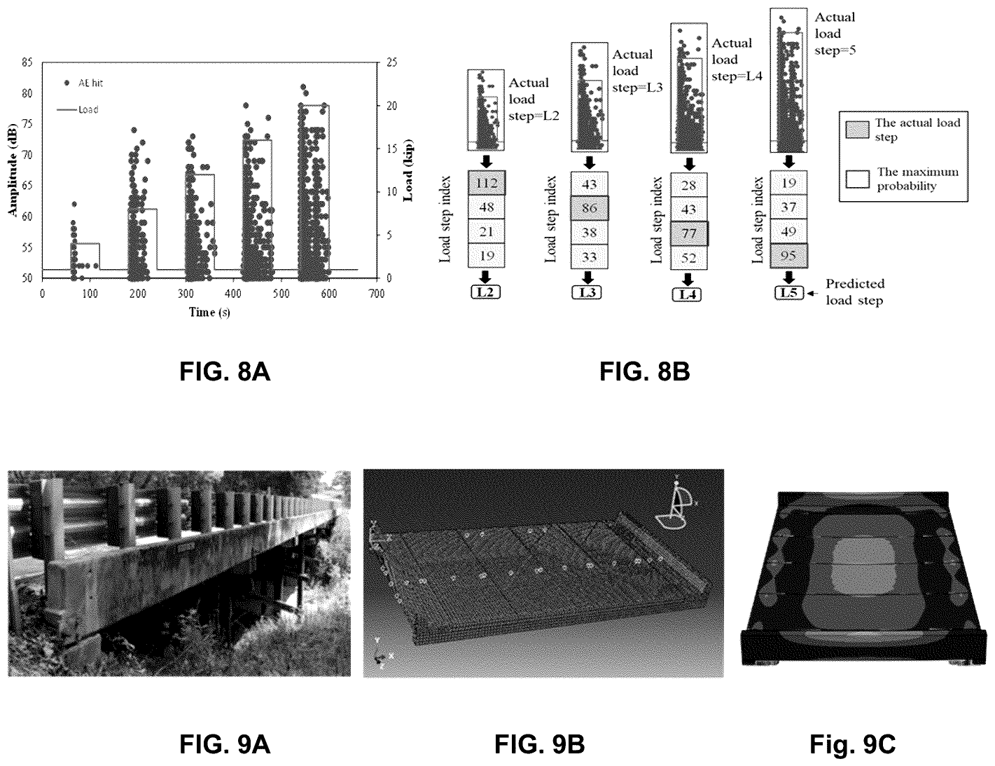

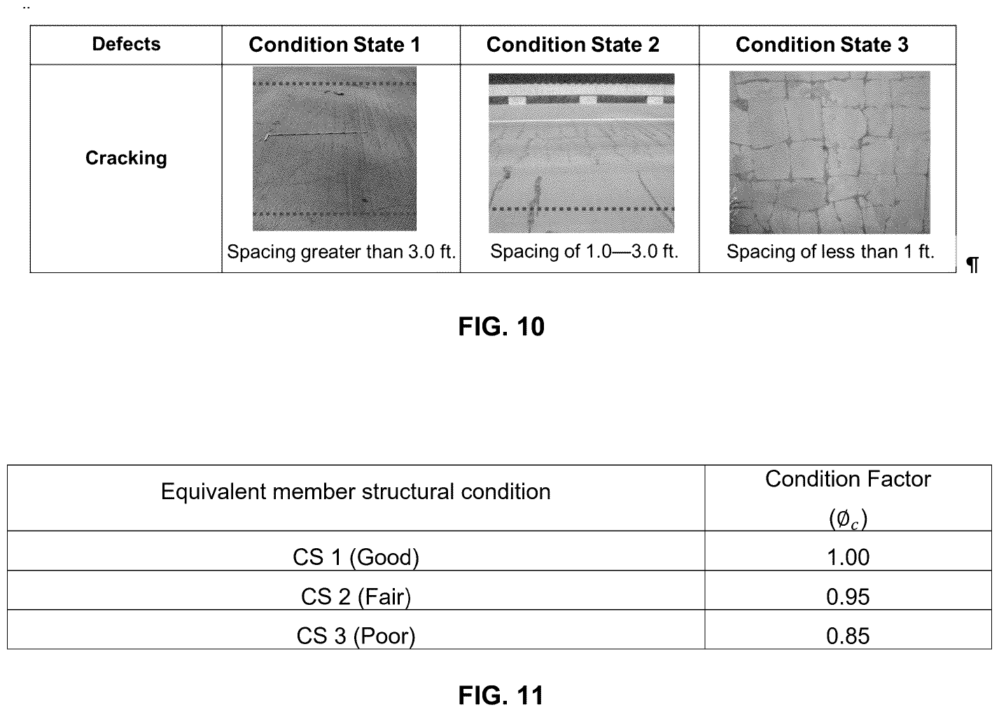

The method described in step 301 was evaluated under laboratory conditions. Referring to FIGS. 8A and 8B, step loading on a concrete specimen to which four AE sensors were attached. The step loading was deigned to simulate the load of a passing vehicle and each load step generated numerous AE signals (dots in FIG. 8A, where each dot represents an AE signal). In this experimental test, the programed probabilistic machine learning algorithm used was random forest. The experimental results are shown in FIG. 8B. For load step L2, 112 AE signals indicated a vehicle load level of L2, 48 signals indicated an impact force of L3, 21 signals leaned towards an impact force of L4, and 19 signals inferred an impact force of L5. Considering all these factors, the majority of decisions supported a load level of L2. Therefore, the method evaluated concluded that the applied load level was L2, which corresponds with the actual condition. The method described in step 301 was further evaluated under differing loads and was found to accurately determine the vehicular load.

The second Step 302 applies the vehicle load, as determined in the first Step 301, to modified bridge model data 77 in the digital twin server 107. In aspects, it is contemplated that the modified bridge model data 77 can represent the entire span of the bridge, a portion of a bridge, and/or a single span of the bridge. In the second Step 302, the processor 25 of the digital twin server can be programed with instructions to apply the AE-derived vehicular load to the modified bridge model data 77 of the digital twin system to obtain the mechanical responses of the bridge, such as estimated displacement and strain resulting from the applied vehicular load. Referring to FIGS. 9A-9C), FIG. 9A shows an actual image of a span of a bridge; FIG. 9B shows a digital twin image of the span of the bridge derived from the modified bridge model data 77; and FIG. 9C shows an image of the span of the bridge after application of the AE-derived vehicular load to the modified bridge model data 77 of the digital twin system to show the determined structural response of the bridge due to the applied vehicular load.

In the third Step 303, the processor 25 of the digital twin server can be programed with instructions to compare the responses obtained from the digital twin system in the second Step 302 such as for example, estimated strain, with the actual strain data measurements obtained from the stain sensors on the bridge, in order to validate and/or update the model digital twin bridge. By periodically or continually validating the determined modified bridge model data and the resulting digital twin bridge model with the strain gauge data, the fidelity of the digital twin bridge model can be ensured, guaranteeing that the digital twin bridge model represents the current state of the bridge.

Subsequently, in the fourth Step 304, the processor 25 of the digital twin server can be programed with instructions to update the estimated condition factor ø_{c} for the bridge slab. In this aspect visual and/or drone inspections of the bridge are conducted periodically or as desired by the operator to visually detect concrete surface cracks and estimate the distance between cracks. Once the crack distances are automatically estimated through visual or drone inspection and applied vision algorithms, the estimated condition factor ø_{c} can be determined.

Conventionally, the Bridge Component Inspection Manual provides a systematic assessment of the structural integrity of concrete bridges, with a particular focus on the presence and spacing of surface cracks. The Bridge Component Inspection Manual illustrates a bridge condition rating system that focuses on the spacing between surface cracks in concrete bridges as a crucial indicator of potential structural damage. The bridge condition rating system is divided into three conditions: Condition 1 (Good), Condition 2 (Fair), and Condition 3 (Poor). Condition 1 (Good) indicates crack spacing greater than 3.0 feet, suggesting minimal structural issues. Conversely, Condition 3 (Poor) indicates crack spacing less than 1 foot, suggesting significant structural problems.

Operationally, the estimated condition factor ø_{c} can be derived based on the Specifications for the National Bridge Inventory. This factor assigns values to the previously discussed condition states: Good, Fair, and Poor. Condition 1 (Good) corresponds to a condition factor of 1.00, indicating the structure is in optimal condition with negligible defects. Condition 2 (Fair) has a condition factor of 0.95, indicating the structural condition is generally acceptable with minor defects. Condition 3 (Poor) has a condition factor of 0.85, indicating significant defects or aging that may threaten the overall integrity of the structure.

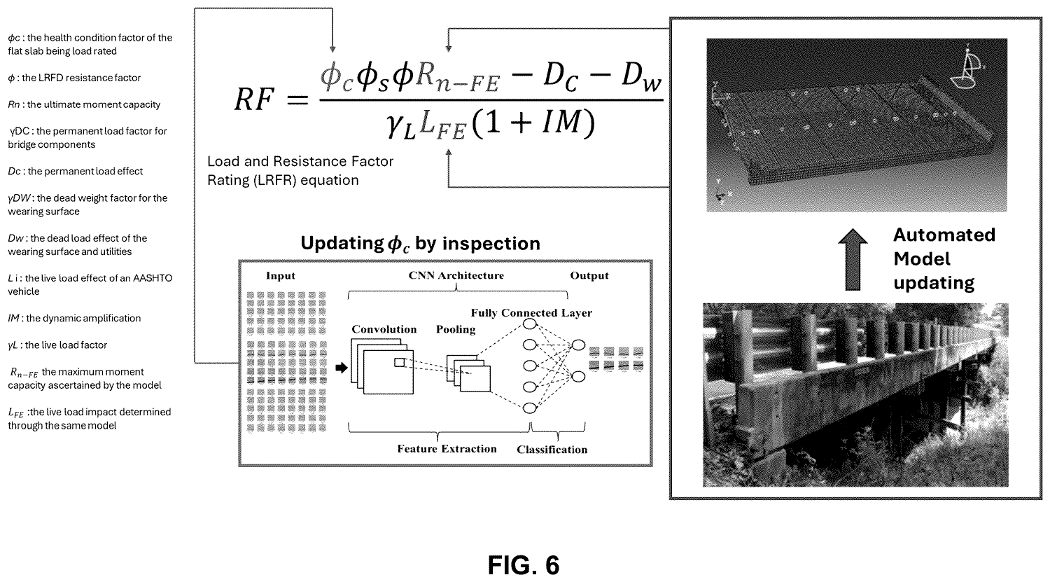

As noted above, in Step 304 it is contemplated that the processor 25 can be programed with instructions that when executed determining any remaining inputs required by bridge rating equation exemplarily illustrated in FIG. 6 such as, for example and without limitation, the maximum moment capacity of the updated digital twin bridge model and the live load impact of the updated digital twin bridge model. Typical inputs can include at least those inputs noted in FIG. 6.

Referring to FIG. 4, in exemplary aspects, in a first Step 401, the processor 25 of the bridge 10 or the digital twin server 107 is programmed to generate a simulating digital twin of the bridge in its “new” state based on bridge design and construction data. As one will appreciate, the bridge design and construction data can comprise digital data that forms a portion of the bridge data that is used to describe/create the simulated or digital twin version of the bridge in the “new” state.

In embodiments, in a second Step 402, the processor 25 of the bridge 10 or the digital twin server 107 is programmed to aggregate bridge data, condition data, sensor data, and load data that describes changes and/or modification of the state of the bridge over time. In this step, it is further contemplated that the bridge data, condition data, sensor data, and load data can be received by the processor on a periodic or continual basis. Optionally, the bridge data, condition data, sensor data, and load data can be received by the processor on a request basis by the operator. As one will appreciate, the updates to the bridge data, condition data, sensor data, and load data can help to update the digital twin bridge model to accurately model the general appreciation or degradation of the state of the real-world bridge.

In embodiments, in a third Step 403, the processor 25 of the bridge 10 or the digital twin server 107 is programmed to update the bridge model data based on the aggregated bridge data, condition data, sensor data, and load data to form a modified bridge model data that accurately models the general appreciation or degradation of the state of the real-world bridge. In this step, it is further contemplated that the bridge model data can be updated by the processor on a periodic or continual basis upon receipt of updated data inputs over time from Step 402.

In embodiments, in a fourth Step 404, the processor 25 of the bridge 10 or the digital twin server 107 is programmed to execute one or more simulations using the modified bridge model data (the updated digital twin bridge model) and a set of simulation data. As one will appreciate, the simulations allow for the modeling of present and/or future performance of the digital twin bridge model that is described by the modified bridge model data. In embodiments, the simulations can be executed upon request or upon a periodic or continual basis. As one will appreciate, the output of the simulations can generate data that can describe the mechanical condition of the real-world bridge.

In embodiments, in a fifth Step 405, the processor 25 of the bridge 10 or the digital twin server 107 is programmed to generate a bridge load rating from the model bridge model data and the aggregated bridge data, condition data, sensor data, load data, and any derived bridge data therefrom (which can include, without limitation, the maximum moment capacity of the updated digital twin bridge model and the live load impact of the updated digital twin bridge model). In this step, the processor 25 of the bridge 10 or the digital twin server 107 can be programmed to execute the load and resistance factor rating (LRFR) equation shown in FIG. 6, which figure also identifies representative bridge and derived bridge data required to perform the determination of the noted load and resistance factor rating of the updated digital twin bridge model. Finally, in embodiments, in a fifth Step 405, the processor 25 of the bridge 10 or the digital twin server 107 can be programmed to generate a report to an end user.

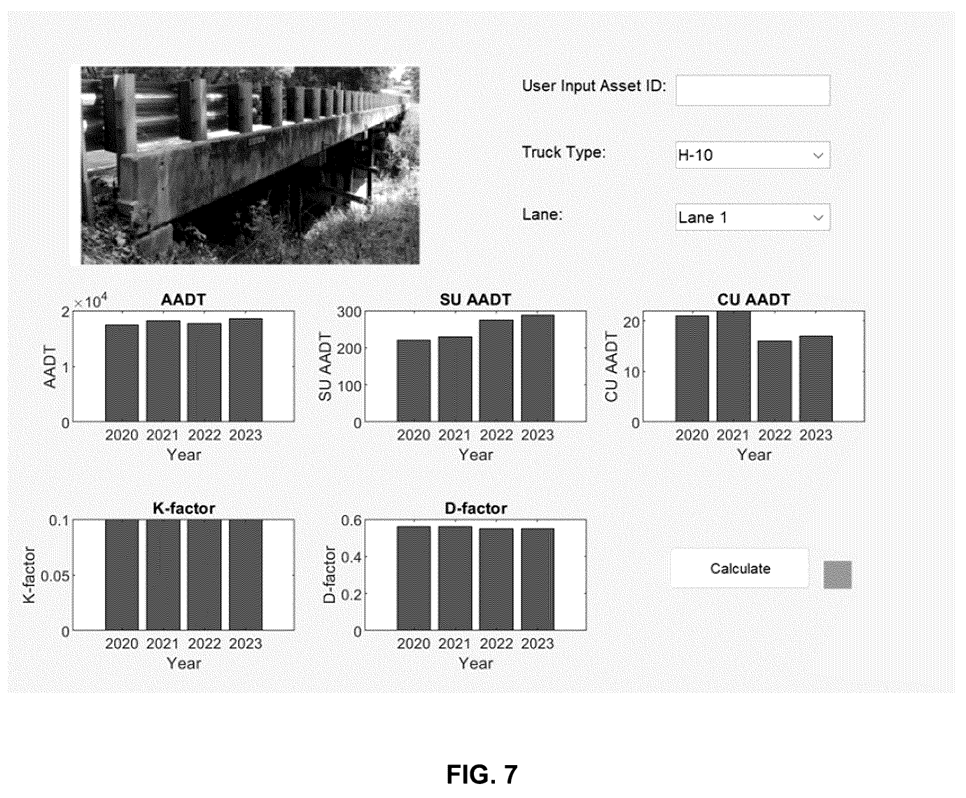

Referring to FIG. 7, which shows a representative GUI interface for requesting the conduct of a simulation. In this exemplary presentation, an operator can input an asset ID that allows for the identification of the real-world bridge of interest and the mirrored digital twin model of the same bridge. In this non-limiting example, at least one of the following can be display of the GUI interface: a photo of the real-world bridge (if available), at least one histogram (if available) showing key traffic indicators for the asset across different years. The at least one histogram for the bridge can be selected from one or more of: AADT (Annual Average Daily Traffic), SU AADT (Single Unit Truck AADT), CU AADT (Commercial Unit Truck AADT), the K factor of the bridge (the K-factor is used to modify the live load distribution factors calculated for a bridge, potentially increasing or decreasing the amount of live load a specific structural component is assumed to carry), and the D factor of the bridge ( the D-factor, or dead load factor, is applied to dead loads (the weight of the bridge structure itself and any permanent attachments like railings or overlays) to account for uncertainties in their magnitude, such as variations in material density or the thickness of overlays)e. In operation, it is contemplated that the operator can select the type or vehicle for the load rating determination and, optionally, can specify the vehicle's position relative to a portion of the bridge. Finally, by selecting the calculate cursor, the load rating factor can be generated through the process outlined above.

In some embodiments, the communication unit 45 includes a cellular communications transceiver for sending and receiving data over a cellular communications network including via short messaging service (SMS), multimedia messaging service (MMS), hypertext transfer protocol (HTTP), direct data connection, WAP, e-mail, or another suitable type of electronic communication. In some embodiments, the communication unit 45 includes a wired port and a wireless transceiver.

The processor 25 can include an arithmetic logic unit, a microprocessor, a general-purpose controller, or some other processor array to perform computations and can provide electronic display signals to a display device. The processor 25 can process data signals and can include various computing architectures including a complex instruction set computer (CISC) architecture, a reduced instruction set computer (RISC) architecture, or an architecture implementing a combination of instruction sets as described herein. The digital control system can include one or more processors. Other processors, operating systems, sensors, displays, and physical configurations can be possible.

The memory 27 stores instructions or data that can be accessed and executed by the processor 25. The instructions or data can include code for performing the techniques described herein. The memory 27 can be a dynamic random-access memory (DRAM) device, a static random-access memory (SRAM) device, flash memory, or some other memory device. In some embodiments, the memory 27 also can include a non-volatile memory or similar permanent storage device and media including a hard disk drive, a floppy disk drive, a CD-ROM device, a DVD-ROM device, a DVD-RAM device, a DVD-RW device, a flash memory device, or some other mass storage device for storing information on a more permanent basis. In aspects, a portion of the memory 27 can be reserved for use as a buffer or virtual random-access memory (virtual RAM).

The processor 25 can include code or routines that, when executed, causes the AE sensor data, and bridge strain data, to be recorded and causes the communication unit to transmit the AE sensor data and bridge strain data to be communicated to the digital twin system of the digital twin server 107 via the network 105. The processor 25 includes code and routines that are operable to collect the AE sensor data 95B and bridge strain data 95A and to store the AE sensor data and bridge strain data in the memory 27 and cause the communication unit 45 of the bridge 110 to transmit the AE sensor data and bridge strain data to the digital twin server 107 in the form of sensor data 56.

In some embodiments, the memory 27 of the digital twin server 107 can store one or more of the following elements: a bridge data set 74; a “new” bridge model data set 76; a condition data set 75; a sensor data set 56; a vehicular load data set 57 (to include vehicular load data derived from the AR sensor data included in the sensor data set 56), a modified bridge model data set 77; a bridge condition data set 75; a simulation data set 55; and report data set 59. In aspects, the bridge data set 74 can include digital data that describes one or more bridge models for one or more real-world bridges such as the bridge 110. In some embodiments, the bridge model data 74 can include digital data that describes design information for the bridge 10 and its individual bridge components.

In embodiments, the digital twin system is configured to generate a digital twin bridge model data set for a particular bridge 110 that is described by an instance of applied bridge data 74 for the particular bridge 110 and can be revised by the digital twin system 199 as instances of at least derived vehicle load data, bridge strain data, and bridge condition data 75 are received over time.

The bridge model data 76 can includes all the digital data necessary to cause a simulation engine to generate a virtual version of a particular bridge 10 (i.e., a digital twin of the particular bridge) in a simulation provided by the simulation engine. The digital twin generated based on the bridge model data 76 represents the particular bridge 110 as designed and constructed. In one exemplary aspect, the digital twin generated based on the bridge model data 76 represents a bridge 110 that is otherwise unaltered from its condition when designed and constructed.

As used here, “the bridge model for this particular bridge 10” means the bridge model data 76 for this particular bridge 10 if no modified bridge model data 77 exists for this particular bridge 110, or the modified bridge model data 77 for this particular bridge 110 if one exists in the memory 27 of the digital twin server 107.

As exemplarily described herein, provided is a method and/or system comprising generating a bridge model of a bridge from bridge model data, (in which the bridge model describes a first digital representation of the bridge as it exists in a real-world); receiving digital data sensed by at least one acoustic emission sensor positioned thereon the bridge; receiving digital data sensed by at least one strain sensor positioned thereon the bridge; determining vehicular load data from the digital data sensed by at least one acoustic emission sensor; applying the vehicular load data to the bridge model to generate, based on the bridge model and the received digital data, a modified bridge model of the bridge that describes a second digital representation of the bridge in an altered condition; determining the estimated mechanical responses of the modified bridge model in response to the applied vehicular load data; validating the modified bridge model by comparing the digital data sensed by at least one strain sensor to the estimated mechanical responses of the modified bridge model acting in response to the applied vehicular load data; determining a condition state of the bridge and updating the modified bridge model in accord with the condition state; retrieving simulation data that describes one or more vehicular loads; executing at least one simulation, each simulation including, based on the modified bridge model and the simulation data, on a digital twin of the bridge in the altered condition operating under the vehicular load; and generating a report describing the bridge based on the at least one executed simulation and the digital twin, wherein the report includes a bridge performance prediction based on the at least one simulation.

In this aspect, the step of determining vehicular load data from the digital data sensed by at least one acoustic emission sensor can comprise applying probabilistic machine learning programming that is configured to convert sensed acoustic emission data to vehicle load data that is indicative of vehicular loads being applied to at least a portion of the bridge or to the bridge. In this aspect, it is contemplated that the probabilistic machine learning algorithm can be configured to allow for the selection of the vehicle load level with the highest level of probability of matching the real-world vehicle passing over the bridge.

In various aspects, it is contemplated that the estimated mechanical responses can include estimated displacements and strain of the modified bridge model. Additionally, it is contemplated that a maximum moment capacity and a live load impact of the updated digital twin bridge model is determined. In other aspects, a bridge load rating for the digital twin of the bridge in the altered condition can be determined based on at least the updated modified bridge model, the bridge model data, the digital data, and the vehicular load data, determining a bridge load rating for the digital twin of the bridge in the altered condition.

In various aspects, it is contemplated that the modified bridge can be validated periodically or continually.

Further, in various aspects, it is contemplated that the condition state of the bridge can be determined by: conducting an inspection of the real-world bridge to detect concrete surface cracks and estimate the distance between cracks; rating the bridge condition based on a bridge condition rating system that focuses on the spacing between surface cracks; and deriving an estimated condition factor ø_{c} from values assigned to the condition state identified under the bridge condition rating system.

The foregoing description of the embodiments of the specification has been presented for the purposes of illustration and description. It is not intended to be exhaustive or to limit the specification to the precise form disclosed. Many modifications and variations are possible in light of the above teaching. It is intended that the scope of the disclosure be limited not by this detailed description, but rather by the claims of this application. As will be understood by those familiar with the art, the specification can be embodied in other specific forms without departing from the spirit or essential characteristics thereof. Likewise, the particular naming and division of the modules, routines, features, attributes, methodologies, and other aspects are not mandatory or significant, and the mechanisms that implement the specification or its features can have different names, divisions, or formats. Furthermore, as will be apparent to one of ordinary skill in the relevant art, the modules, routines, features, attributes, methodologies, and other aspects of the disclosure can be implemented as software, hardware, firmware, or any combination of the three. Also, wherever a component, an example of which is a module, of the specification is implemented as software, the component can be implemented as a standalone program, as part of a larger program, as a plurality of separate programs, as a statically or dynamically linked library, as a kernel-loadable module, as a device driver, or in every and any other way known now or in the future to those of ordinary skill in the art of computer programming. Additionally, the disclosure is in no way limited to embodiment in any specific programming language, or for any specific operating system or environment. Accordingly, the disclosure is intended to be illustrative, but not limiting, of the scope of the specification, which is set forth in the following claims.

What is claimed is:

1. A method comprising:
generating a bridge model of a bridge from bridge model data, wherein the bridge model describes a first digital representation of the bridge as it exists in a real-world;
receiving digital data sensed by at least one acoustic emission sensor positioned thereon the bridge;
receiving digital data sensed by at least one strain sensor positioned thereon the bridge;
determining vehicular load data from the digital data sensed by at least one acoustic emission sensor;
applying the vehicular load data to the bridge model to generate, based on the bridge model and the received digital data, a modified bridge model of the bridge that describes a second digital representation of the bridge in an altered condition;
determining the estimated mechanical responses of the modified bridge model in response to the applied vehicular load data;
validating the modified bridge model by comparing the digital data sensed by at least one strain sensor to the estimated mechanical responses of the modified bridge model acting in response to the applied vehicular load data;
determining a condition state of the bridge and updating the modified bridge model in accord with the condition state;
retrieving simulation data that describes one or more vehicular loads;
executing at least one simulation, each simulation including, based on the modified bridge model and the simulation data, on a digital twin of the bridge in the altered condition operating under the vehicular load; and
generating a report describing the bridge based on the at least one executed simulation and the digital twin, wherein the report includes a bridge performance prediction based on the at least one simulation.

2. The method of claim 1, wherein the step of determining vehicular load data from the digital data sensed by at least one acoustic emission sensor comprises applying probabilistic machine learning algorithm that are configured to convert sensed acoustic emission data to vehicle load data that is indicative of vehicular loads being applied to at least a portion of the bridge or to the bridge.

3. The method of claim 2, wherein the probabilistic machine learning algorithm is configured to allow for the selection of the vehicle load level with the highest level of probability of matching the real-world vehicle passing over the bridge.

4. The method of claim 1, wherein the estimated mechanical responses can include estimated displacements and strain of the modified bridge model.

5. The method of claim 1, further comprising, for the updated modified bridge model, the step of determining a maximum moment capacity and a live load impact of the updated digital twin bridge model.

6. The method of claim 5, further comprising, based on at least the updated modified bridge model, the bridge model data, the digital data, and the vehicular load data, determining a bridge load rating for the digital twin of the bridge in the altered condition.

7. The method of claim 1, wherein the step of validating the modified bridge is conducted periodically or continually.

8. The method of claim 1, wherein the step of determining a condition state of the bridge comprises:
conducting an inspection of the real-world bridge to detect concrete surface cracks and estimate the distance between cracks;
rating the bridge condition based on a bridge condition rating system that focuses on the spacing between surface cracks; and
deriving an estimated condition factor ø_{c} from values assigned to the condition state identified under the bridge condition rating system.

9. A system comprising:
at least one acoustic emission sensor positioned hereon a real-world bridge;
at least one strain sensor positioned hereon a real-world bridge;
a non-transitory memory storing digital data recorded by the at least one acoustic emission sensor and the at least one and describing the real-world bridge; and
a processor that is communicatively coupled to the non-transitory memory, wherein the non-transitory memory stores computer code which, when executed by the processor, causes the processor to:
determine vehicular load data from the digital data sensed by at least one acoustic emission sensor;
apply vehicular load data to the bridge model to generate, based on the bridge model and the received digital data, a modified bridge model of the bridge that describes a second digital representation of the bridge in an altered condition;
determine the estimated mechanical responses of the modified bridge model in response to the applied vehicular load data;
validate the modified bridge model by comparing the digital data sensed by at least one strain sensor to the estimated mechanical responses of the modified bridge model acting in response to the applied vehicular load data;
determine a condition state of the bridge and updating the modified bridge model in accord with the condition state;
retrieve simulation data that describes one or more vehicular loads;
execute at least one simulation, each simulation including, based on the modified bridge model and the simulation data, on a digital twin of the bridge in the altered condition operating under the vehicular load; and
generate a report describing the bridge based on the at least one executed simulation and the digital twin, wherein the report includes a bridge performance prediction based on the at least one simulation.

10. The system of claim 9, wherein the processor applies probabilistic machine learning computer code that, when executed, converts sensed acoustic emission digital data to vehicle load data that is indicative of vehicular loads being applied to at least a portion of the bridge or to the bridge.

11. The system of claim 10, wherein the probabilistic machine learning computer code allows for the selection of the vehicle load level with the highest level of probability of matching the real-world vehicle passing over the bridge.

12. The system of claim 9, wherein the estimated mechanical responses can include estimated displacements and strain of the modified bridge model.

13. The system of claim 9, further comprising, for the updated modified bridge model, the step of determining a maximum moment capacity and a live load impact of the updated digital twin bridge model.

14. The system of claim 13, wherein the processor is further programmed to determine a bridge load rating for the digital twin of the bridge in the altered condition based on at least the updated modified bridge model, the bridge model data, the digital data, and the vehicular load data.

15. The system of claim 9, further comprising updating the modified bridge model in real-time based on a feedback loop.

16. The system of claim 9, further comprising updating the modified bridge model periodically.

17. The system of claim 9, further comprising storing condition data in the non-transitory memory that causes the processor to determine the condition state of the bridge.

18. The system of claim 17, wherein the condition data includes data that results from: the conduct of an inspection of the real-world bridge to detect concrete surface cracks and to estimate the distance between cracks, derivation of a rating the bridge condition based on a bridge condition rating system that focuses on the spacing between surface cracks; and derivation of an estimated condition factor ø_{c} from values assigned to the condition state identified under the bridge condition rating system.
